(19) United States
(12) Patent Application Publication
(10) Pub. No.: US 2008/0054259 A1
(43) Pub. Date: Mar. 6, 2008

(54) Semiconductor Component with an Electric Contact Arranged on at Least One Surface

(76) Inventors: Stefan Glunz, Freiburg (DE); Ansgar Mette, Freiburg (DE); Ralf Preu, Freiburg (DE); Christian Schetter, Freiburg (DE)

Correspondence Address: GREENBLUM & BERNSTEIN, P.L.C., 1950 ROLAND CLARKE PLACE, RESTON, VA, 20191, US

(21) Appl. No.: 11/572,087

(22) PCT Filed: Jul. 15, 2005
(86) PCT No.: PCT/EP05/07711

§ 371 Date: Jul. 12, 2007

(30) Foreign Application Priority Data
Jul. 16, 2004 (DE) 10 2004 034 435.3

(51) Int. Cl. H01L 31/0352; H01L 21/02

(52) U.S. Cl. 257/41; 438/83; 257/E21.002; 257/E31.039

(57) ABSTRACT

A semiconductor component includes at least one surface, at least one trench formed in the at least one surface and at least one edge structured and arranged on the at least one surface and formed by the at least one trench. Additionally, the semiconductor component includes an electric contact arranged on the at least one edge, wherein the at least one surface provides for at least one of electric and optical power input and output to the semiconductor component.

### CROSS-REFERENCE TO RELATED APPLICATIONS

The present application is a U.S. National Stage Application of International Application No. PCT/EP2005/007711 filed Jul. 15, 2005, which published as WO 2006/008080 A1 on Jan. 26, 2006 and claims priority under 35 U.S.C. § 119 and § 365 of German Application No. 10 2004 034 435.3 filed Jul. 16, 2004.

### BACKGROUND OF THE INVENTION

1. Field of the Invention

The invention relates to a semiconductor component with an electric contact arranged on at least one surface, with which electric as well as optical power can be introduced into the semiconductor component and/or decoupled therefrom via this surface. In particular the invention relates to a solar cell or a high-performance light-emitting diode.

2. Description of Background Information

Large currents flow through semiconductor components with high power densities. Large conductor cross sections are necessary in order to supply these currents to or to remove these currents from the active semiconductor layer in a low-loss manner. To this end large-area metal contacts are often attached to the semiconductor surface. However, with optoelectronic semiconductor components there is the additional problem that light must also be introduced into or decoupled from a surface of the components. The conductor structures thus cannot be embodied across this entire surface.

In order to nevertheless retain large conductor cross sections, the aim is to apply to the component a strip-shaped metallization that has a narrow width while at the same time a great height or thickness to increase the conductor cross section. It is thus possible to supply or remove high currents in a low-loss manner via the conductor surface and at the same time to introduce or decouple light via the uncovered surface areas.

Various methods are customary in order to produce the contact structures described. These can be assigned either to thick-film technology or to thin-film technology. In thick-film technology a metal-containing paste is applied to the surface in a printing step and connected to the surface and sintered to form a conductor path in a subsequent high-temperature step. The application of the metal-containing paste can take place thereby either in a screen printing process, in a pad printing process or by paste scribing. The smallest achievable structural width is thereby 50-80 μm with a maximum layer thickness of approximately 10 μm.

Thin-film methods include, e.g., photolithography. In this case the substrate to be metallized is coated with a photoresist that is structured by exposure and development. The metal contacts are then applied in the predetermined area regions by vapor-depositing or sputtering one or more metal layers. Since in this case the greatest possible thickness of the metallization is limited by the thickness of the photoresist, as a rule there is an absolute limit for the layer thickness of approximately 10 μm.

Furthermore, it is known to improve the height to width ratio by subsequent tin plating of the conductor paths. Thus, e.g., with the tin plating of a conductor produced by photolithography with a thickness of 10 μm and a width of 193 μm with a wetting angle of 45° of the liquid tin, a height to width ratio of 0.26 is achieved. In comparison, the conductor path not tin plated has a ratio of 0.05.

Large height to width ratios, i.e., values around or above 1, cannot be achieved with any of the above-mentioned metallization methods. Furthermore, all the methods mentioned comprise several process steps and are therefore cost-intensive and error-prone in industrial mass production.

U.S. Pat. No. 5,468,652 discloses a solar cell in which the shading of the front side is prevented by holes being provided in the substrate through which the upper side can be contacted. The disadvantage of this solar cell is the fact that this method contains many process steps and is too complex for industrial production.

EP 1 182 709 A1 discloses a method for producing metal contacts in which trenches are arranged on the front face of the solar cell, which trenches accommodate a metal contact. To this end first one or more grooves are made in the face of the solar cell. Subsequently, a seed layer is applied to the inside thereof by electroless plating and sintering. In a further process step a contact layer is deposited on the seed layer and the trench is completely filled with copper. In this manner the limitations of the thick-film and thin-film methods described can be avoided. However, the trenches have to be doped before the metallization. This further process step increases both the expense and the fault susceptibility of the method and reduces the active layer thickness of the semiconductor material.

### SUMMARY OF THE INVENTION

Accordingly, the aim of the present invention is to disclose a semiconductor component and a method for the production thereof in which metal contacts can be produced on semiconductor surfaces in a simple manner with few process steps. The semiconductor surfaces include a large conductor cross section and little shading. In particular contact structures are to be produced which have a height to width ratio of approximately 1.

According to the invention, a semiconductor component with an electric contact arranged on at least one surface, with which electric as well as optical power can be introduced (or input) into the semiconductor component and/or decoupled (or output) therefrom via this surface. Moreover, the contact is arranged on at least one edge arranged on the surface and can be obtained by the galvanic or electroless deposition of a metal or of an alloy. Furthermore, the aim is attained through a method for producing a semiconductor component in which first an edge is embodied on a surface of the semiconductor, and subsequently, a contact is deposited on the edge in a galvanic or electroless manner with the simultaneous irradiation with light.

According to the invention, it was recognized that a contact can be produced on an edge of a semiconductor material in a galvanic or electroless manner, which contact has a virtually round cross section. With the contact according to the invention the height to width ratio is thus substantially enlarged compared to the flat contacts according to the prior art. The embodiment of the contact according to the invention, with the galvanic or electroless deposition, is based on the one hand on the fact that the field strength shows an excessive increase on the surface of pointed structures. Therefore metal ions from an electroplating bath are preferably deposited on these pointed structures or edges.

Furthermore, the production method according to the invention utilizes the internal photoeffect of a photovoltaic component. In this regard, the internal photoeffect can be considered the spatial separation of positive and negative charge carriers under light incidence in a pn transition region.

According to the invention, it was recognized that metal ions from a deposition bath under light incidence preferably attach themselves along the edge. This effect occurs when the irradiated photons have an energy above the bandgap energy. For example, a laser or a light-emitting diode are suitable for the illumination. Additionally, a commercial halogen lamp represents a particularly simple light source.

An edge provided to accommodate a contact can be embodied, e.g., by a trench being made in the surface of the semiconductor substrate. In this manner the number, size and type of the metal contacts on the surface can be established as desired. Since the metal contact is arranged only on the edge of the trench, the area not covered by the contact can continue to be used as entrance or exit surface for photons.

The trench made can thereby have any desired cross section. For example, rectangular, square or irregularly formed cross sections would be conceivable here. However, a U-shaped or V-shaped trench is particularly preferred. The V-shaped trench thereby has a triangular cross-section. The U-shaped trench has a cross section that has a round cross section at its deepest point, i.e., that point that is furthest removed from the surface, but the side surfaces can be arranged perpendicular or tilted. In particular the V-shaped trench is characterized in that light that is incident on the surface is introduced particularly efficiently into the semiconductor.

A very particularly preferred embodiment is characterized in that two U-shaped or V-shaped trenches partially overlap so that a sharp edge is formed at their contact line.

The resulting trench accordingly has a W-shaped cross section, whereby the contact according to the invention is formed on the center tip of the W-shaped trench. Through this geometric embodiment of the contact zone a particularly sharp edge is achieved, which facilitates the production of the contact according to the invention through a large excessive field increase.

According to the invention the trenches are produced by machining or by etching or by laser ablation. One skilled in the art will consider sawing, milling or grinding for the machining. Etching can be carried out in a wet-chemical as well as in a dry-chemical manner.

In a preferred embodiment the edge has an angle of approximately 5° to approximately 120°, particularly preferably approximately 45° to approximately 65°. It has been shown that in this angle range the edge can be produced in a simple manner and the excessive field increase is also sufficient to produce the contact. The depth of the trench is thereby preferably approximately 1 μm to approximately 100 μm, particularly preferably approximately 20 μm to approximately 50 μm. This range is established because on the one hand sufficient excessive field increase does not occur with flatter trench structures, on the other hand the stability of the component is impaired in a disadvantageous manner with deeper structures.

Through the electron excess on an n-doped semiconductor layer, metal ions are deposited from the aqueous solution and form an electric contact. It has been shown that in particular n-doped layers with a specific resistance of 30 Ω/sq to 140 Ω/sq can be contacted with the method according to the invention. The SI representation of the unit Ω/sq is thereby V/A·cm/cm and is familiar to one skilled in the art for giving the specific resistance of an emitter layer. The method can be used particularly preferably for the metallization of an n-doped emitter layer of a solar cell.

Although ohmic contacts as well as Schottky contacts can be produced with the method according to the invention, the method is particularly suitable for the production of low-resistance contacts on power semiconductors such as, e.g., solar cells or high-performance light-emitting diodes. The contact according to the invention can be embodied on elemental semiconductors or compound semiconductors. The contact is particularly suitable for contacting semiconductor components on silicon substrates.

Depending on the semiconductor material used, one skilled in the art will consider in particular nickel and/or silver and/or tin and/or titanium and/or aluminum and/or palladium and/or copper and/or chromium to produce the contact. In particular, one skilled in the art will also consider alloys of the metals mentioned.

In an advantageous further development of the invention, after deposition of the metallic contact the component is sintered at a temperature between 660 K and 740 K, in particular at a temperature of 698 K, to reduce the transition resistance between the metal contact and the semiconductor material. Through this process step, on the one hand, an alloy is formed and thus a change occurs in the work function within the metal layer, so that the Schottky barrier is further reduced with the correct choice of composition as a function of the semiconductor base material. Furthermore, the sintering step causes a connection of the metal with the semiconductor material lying underneath it with simultaneous alloy formation in the transition region.

A particularly strong contact with particularly low transition resistance is achieved with an embodiment of the method in which the edge is roughened before deposition of the contact. This roughening can be carried out either mechanically by machining with geometrically determinate or indeterminate cutting and/or by etching. If an etching step is provided for the roughening, one skilled in the art will naturally consider both a wet chemical and a dry chemical etching step.

### BRIEF DESCRIPTION OF THE DRAWINGS

The invention is described in more detail below on the basis of an exemplary embodiment and several figures, in which:

FIG. 1 shows a solar cell according to the prior art;

FIG. 2 shows a solar cell produced according to the invention;

FIG. 3 shows a wafer subjected to a galvanic deposition in a bath to form the contacts on the tips of the W-shaped trench according to the invention; and

FIG. 4 shows images by scanning electron microscope of the semiconductor contact according to the invention.

### DETAILED DESCRIPTION OF THE INVENTION

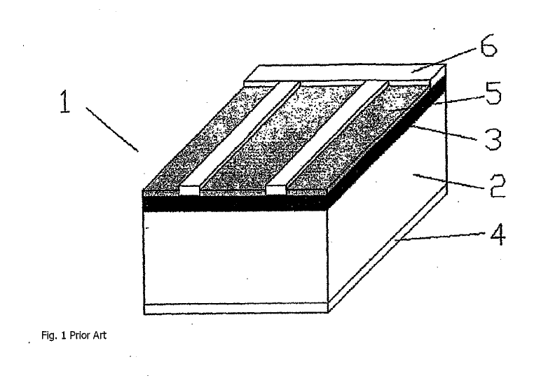

FIG. 1 shows a solar cell 1 according to the prior art. To produce the solar cell 1, a flat back contact 4 is applied on a p-doped silicon substrate 2 as base region. The production of an n-doped emitter layer 3 takes place on the opposite side of the p-doped silicon substrate 2. To protect against environmental effects and to increase the optical efficiency, an antireflection and passivation layer 5 is applied to the solar cell according to the prior art. Metallic contacts 6 are applied in predetermined area regions which are excluded from the antireflection and passivation layer 5 to dissipate the generated current. These contacts 6 typically have widths of 80-100 μm with thicknesses of less than 10 μm. In some cases these contacts 6 can be further strengthened by tin plating or galvanic deposition.

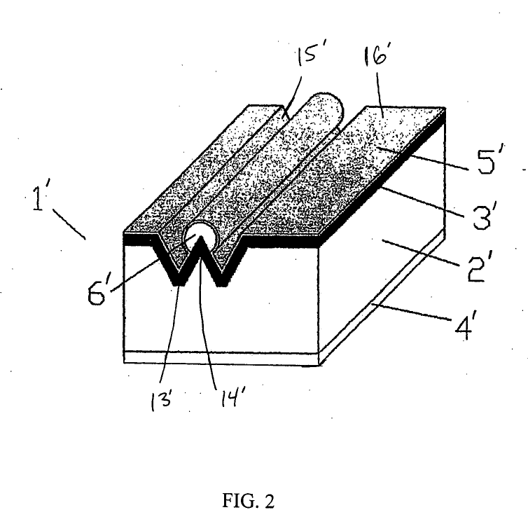

FIG. 2 shows a solar cell 1′ produced according to the invention. Again, a back contact 4′ is applied on a p-doped base material 2′. The opposite side of the p-doped base material 2′ is covered with V-shaped trenches 13′ by machining with a fine saw blade. The cutting guidance thereby takes place such that the V-shaped trenches 13′ partially overlap and the cross section of the V-shaped trenches 13′ thus produced takes on the shape of a “W.” Saw damage to the surface is leveled by an etching step. After this step the V-shaped trenches 13′ have a depth of 30 μm and the center tip 14′ shows an angle of approximately 60°. On the surface thus structured, a low-resistance emitter 3′ is produced through co-diffusion. Additionally, to protect against environmental effects and to increase the optical efficiency, an antireflection and passivation layer 5′ is applied to the solar cell according to the prior art.

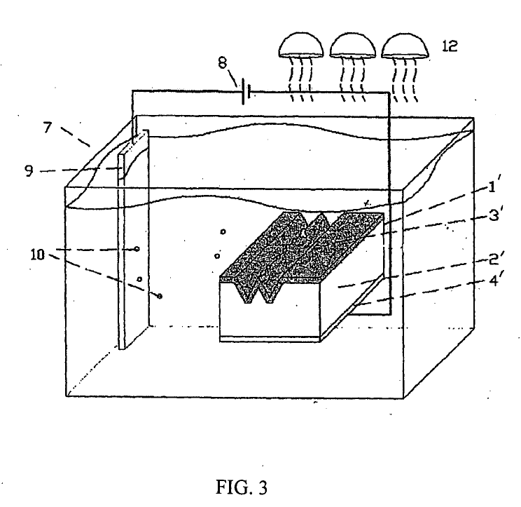

FIG. 3 shows how the wafer is subjected to a galvanic deposition in a bath 7 containing K(Ag(CN)₂) to form the contacts on the center tips 14′ of the W-shaped trench (formed by the partially overlapping V-shaped trenches 13′). To this end, the wafer (i.e., the yet completed solar cell 1′) is acted on with a current density of 1 A/dm² by voltage source 8 via electrode plate 9, with simultaneous irradiation by halogen lamps 12. Within one minute, metal ions 10 are deposited from the aqueous solution to the center tip 14′ to form a closed silver layer contact 6′ (shown in FIG. 2). After a sintering step at 698 K, the contacts 6′ thus formed can be strengthened by another galvanic step. The contacts 6′ thus produced have an essentially round cross section, and accordingly, have an improved height to width ratio compared to the prior art. The areas 15′ of the W-shaped trenches not covered by the contact 6′ are effective as active light-absorbing surfaces, just like the level areas 16′ lying between them. The current-carrying capacity is increased, as is the size of the light-absorbing surfaces.

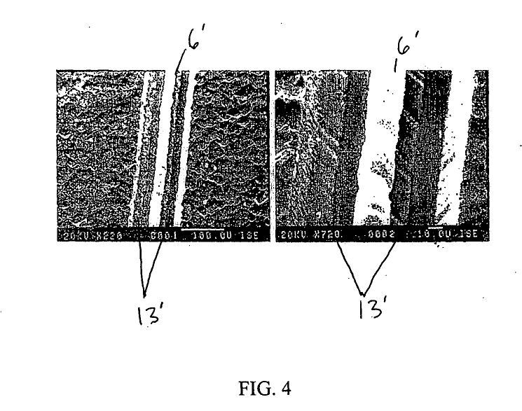

FIG. 4 shows images by scanning electron microscope of the semiconductor contact 6′ according to the invention at two different magnifications. In the central section of the images, the two V-shaped trenches 13′ are clearly discernible, on the inner contact line of which the metal contact 6′ is applied.

1.-23. (canceled)

24. A semiconductor component, comprising:
at least one surface;
at least one trench formed in the at least one surface;
at least one edge structured and arranged on the at least one surface and formed by the at least one trench; and
an electric contact arranged on the at least one edge,
wherein the at least one surface provides for at least one of electric and optical power input and output to the semiconductor component.

25. The semiconductor component of claim 24, wherein the electric contact is formed by one of galvanic and electroless deposition of a metal or an alloy.

26. The semiconductor component of claim 24, wherein the at least one trench comprises two trenches, and the at least one edge is formed by a contact line of the two trenches.

27. The semiconductor component of claim 24, wherein the at least one trench comprises a V-shape or a U-shape.

28. The semiconductor component of claim 24, wherein the at least one edge comprises an angle of approximately 5° to approximately 120°.

29. The semiconductor component of claim 28, wherein the at least one edge comprises an angle of approximately 45° to approximately 65°.

30. The semiconductor component of claim 29, wherein the at least one edge comprises an angle of approximately 60°.

31. The semiconductor component of claim 24, wherein the at least one trench comprises a depth of approximately 1 μm to approximately 100 μm.

32. The semiconductor component of claim 31, wherein the at least one trench comprises the depth of approximately 20 μm to approximately 50 μm.

33. The semiconductor component of claim 24, wherein the at least one surface comprises an n-doped emitter layer.

34. The semiconductor component of claim 33, wherein the n-doped emitter layer comprises a specific resistance of 30 ohm/sq. to 140 ohm/sq.

35. The semiconductor component of claim 24, wherein electric contact comprises an ohmic contact.

36. The semiconductor component of claim 24, wherein the electric contact comprises at least one of Ni, Ag, Sn, Ti, Al, Pd, Cu and Cr.

37. The semiconductor component of claim 24, further comprising a base material that comprises silicon.

38. The semiconductor component of claim 24, wherein the semiconductor component is structured and arranged as a solar cell.

39. A method for producing a semiconductor component, comprising:
creating at least one edge on at least one surface of the semiconductor component by forming at least one trench in the at least one surface; and
forming a contact on the at least one edge through one of a galvanic or an electroless deposition with a concurrent irradiation with light.

40. The method of claim 39, wherein the concurrent irradiation with light provides a photon energy which is greater than or equal to a bandgap of the semiconductor material.

41. The method of claim 39, further comprising sintering the contact after the one of the galvanic or the electroless deposition.

42. The method of claim 41, wherein the contact is sintered at a temperature between 660 K and 740 K.

43. The method of claim 39, wherein the forming of the at least one trench comprises forming two contacting trenches, wherein the at least one edge is formed by a contact line of the two trenches.

44. The method of claim 43, wherein the two contacting trenches at least partially overlap.

45. The method of claim 39, wherein the creating the at least one edge further comprises one of laser radiation, plasma action or machining.

46. The method of claim 39, further comprising roughening the at least one edge by at least one of a mechanical process and an etching process.

47. The method of claim 39, wherein the one of the galvanic or the electroless deposition of the contact comprises a deposition of at least one of Ni, Ag, Sn, Ti, Al, Pd, Cu and Cr.

48. The method of claim 39, wherein the concurrent irradiation with light comprises irradiation by at least one halogen lamp.

49. The method of claim 39, wherein the semiconductor component is structured and arranged as at least one solar cell.
